(19) United States
(12) Patent Application Publication
(10) Pub. No.: US 2016/0219673 A1
(43) Pub. Date: Jul. 28, 2016

(54) OPTOELECTRONIC COMPONENT DEVICE AND METHOD FOR OPERATING AN OPTOELECTRONIC COMPONENT

(71) Applicant: OSRAM OLED GMBH, Regensburg (DE)

(72) Inventor: Arndt Jaeger, Regensburg (DE)

(21) Appl. No.: 15/023,704

(22) PCT Filed: Aug. 22, 2014
(86) PCT No.: PCT/EP2014/067918

§ 371 Date: Mar. 22, 2016

(30) Foreign Application Priority Data
Sep. 23, 2013 (DE) 10 2013 110 483.5

(51) Int. Cl. H05B 33/08; H01L 27/32

(52) U.S. Cl. CPC H05B 33/0896; H01L 27/3209

(57) ABSTRACT

Various embodiments may relate to an optoelectronic component device, including an optoelectronic component and a control device for driving the optoelectronic component. The optoelectronic component includes a first optically active structure and a second optically active structure. The first optically active structure is designed for emitting a first electromagnetic radiation and ages in accordance with a first ageing function during operation. The second optically active structure is designed for emitting a second electromagnetic radiation and ages in accordance with a second ageing function during operation. The optoelectronic component is formed in such a way that at least the first electromagnetic radiation is emitted in a first operating mode and at least the second electromagnetic radiation is emitted in a second operating mode. The control device is designed so as to reduce the difference between first ageing function and second ageing function during the operation of the optoelectronic component device.

### RELATED APPLICATIONS

The present application is a national stage entry according to 35 U.S.C. §371 of PCT application No.: PCT/EP2014/067918 filed on Aug. 22, 2014, which claims priority from German application No.: 10 2013 110 483.5 filed on Sep. 23, 2013, and is incorporated herein by reference in its entirety.

### TECHNICAL FIELD

In various embodiments, an optoelectronic component device and a method for operating an optoelectronic component are provided.

### SUMMARY

Optoelectronic components on an organic basis, for example organic light emitting diodes (OLEDs), are being increasingly widely used in general lighting. An organic optoelectronic component (illustrated in FIG. 1A), for example an OLED, may include above a substrate 102 an anode 104 and a cathode 106 with an organic functional layer system 108 therebetween. The organic functional layer system 108 may include one or a plurality of emitter layer(s) 110, 112, 114 in which electromagnetic radiation is generated (FIG. 1B), one or a plurality of charge generating layer structure(s) each composed of two or more charge generating layers (CGL) for charge generation, and one or a plurality of electron blocking layer(s) 116, also designated as hole transport layer(s) 116 (HTL), and one or a plurality of hole blocking layer(s) 118, also designated as electron transport layer(s) 118 (ETL), in order to direct the current flow. A typical construction of a white OLED includes a stack of emitter layers 110, 112, 114 between the electrodes 104, 106. The stack of emitter layers may include a first organic emitter layer 110, which emits a red light 120; a second organic emitter layer 112, which emits a green light 122, and a third organic emitter layer 114, which emits a blue light 124. During operation, a voltage 126 is applied to the electrodes 104, 106 and the resulting current flows in a kind of series circuit through the emitter layers 110, 112, 114. As a result, the emitter layers 110, 112, 114 can emit light which appears white, for example, in the mixture. The wavelength spectrum emitted by a white OLED is illustrated for example in FIG. 1B as spectral power 128 as a function of the wavelength 130.

Furthermore, FIG. 1B illustrates the spectra in the case of different luminances for an organic light emitting diode after production (reference sign 160) and after 350 operating hours (reference sign 162).

White organic light emitting diodes having product-suitable lifetimes of greater than 10 000 hours have already been demonstrated. Within this lifetime 144 (FIG. 1C), which is also designated as LT70, the luminance is permitted to fall to 70% of the initial luminance before the OLED should be replaced. A fall in luminance to 50% of the original luminance is also designated as LT50 (FIG. 1C).

The human eye can be so sensitive that even small deviations from the specified colour locus can be perceived. The colour locus of the light emitted by the white OLED is therefore permitted to change only minimally during ageing. Deviations from the specified colour locus of approximately +/−0.02 in the CIE values Cx and Cy can be afforded tolerance in general lighting.

The emitter layers 110, 112, 114 of a white OLED may consist of different materials and make different contributions to the total emission. In the white OLED illustrated in FIGS. 1A-1D, a first emitter layer 110 composed of the red phosphorescence substance MDQ, a second emitter layer 112 composed of the green phosphorescence substance Irppy and a third emitter layer 114 composed of the blue fluorescence substance SEB-097 have been used in order to achieve a warm-white colour locus of the emitted light (CIE colour locus coordinates: Cx=0.45, Cy=0.41).

The emitter layers 110, 112, 114 can be formed in such a way that the fall in the normalized luminance 132 as a function of the operating period 134 follows a profile which is similar for all emitter materials and which can be described approximately by a stretched, exponential decay (FIG. 1C). FIG. 1C illustrates the luminance L normalized to the initial luminance L₀ as a function of the operating period t for the emitter layer 110, 136 which emits red light, the emitter layer 112, 138 which emits green light, the emitter layer 114, 140 which emits blue light; the total emission 142 in an emitter layer stack produces a white light.

Different proportions of a red light, a green light and a blue light are necessary for forming white light. The first emitter layer 110, emitting red light, is operated with the highest luminance (7200 cd/m²) in order to set the warm-white colour locus with respect to the other emitter layers 112, 114 at the operating current and therefore has the shortest lifetime LT70—illustrated in FIG. 1B and FIG. 1C by means of a greater fall in the luminance 132 and the spectral power 128 in comparison with that of the second emitter layer 112, 138 and of the third emitter layer 114, 140. In other words: the second emitter layer 112 and the third emitter layer 114 are operated with lower luminance than the first emitter layer, in order to set the warm-white colour locus; second emitter layer 112 (green): 2000 cd/m²; third emitter layer 114 (blue): 800 cd/m². The normalized luminances 132 (normalized to the luminance L₀ after production) as a function of the operating time 134 of the emitter layers 110, 112, 114, as illustrated in FIG. 1C, were determined from an accelerated ageing test using a 10-fold higher operating current. The emitter layers 110, 112, 114 therefore have a lifetime of: first emitter layer 110: LT70=125 h; second emitter layer 112: LT70=200 h; and third emitter layer 114: LT70=260 h. The lifetimes of the second emitter layer 112, 138 and of the third emitter layer 114, 140 are higher than the lifetime of the first emitter layer 110, 136, since the first emitter layer 110, 136, for setting the colour locus of the emitted white light of the emitter layer stack, is operated with a higher luminance than the second emitter layer 112, 138 and the third emitter layer 114, 140.

The ageing functions of the emitter layers 110, 112, 114 can be determined from the profile of the normalized luminance 132 as a function of the operating period 134. The emitter layers 110, 112, 114 can be formed in such a way that their ageing behaviour (L/L₀(t)) can be described by a stretched exponential function of the form exp−(t/τᵢ)^{β}. In this case, L is the luminance 132 at the operating time 134 t; L₀ is the initial luminance; τᵢ is a specific constant that is dependent on the emitter material of an emitter layer; and β is an ageing coefficient. The emitter layers 110, 112, 114 are formed in such a way that they have an approximately identical ageing coefficient β having a value of approximately 0.7. In the various emitter layers 110, 112, 114, however, different ageing processes can take place, such that the emitter layers 110, 112, 114 have different values for τᵢ. As a result, the emitter layers 110, 112, 114 of the white OLED can have different lifetimes LT70 at an operating current (FIG. 1B)—see operating period 134 of the luminance 144 with respect to LT70 of the emitter layers 136, 138, 140, 142.

The total lifetime of the white OLED 142 is determined by the emitter layer 110, 112, 114 which makes the greatest contribution to the emission—here the first emitter layer 110, 136. As a result, the warm-white OLED 142 can have an operating period of only 150 h. If the other two emitter layers have a significantly shorter or longer lifetime, a differential colour ageing can additionally occur, i.e. a deviation of the colour locus from the specified colour locus by means of ageing during the operation of the optoelectronic component. This is illustrated for the above-described warm-white OLED in FIG. 1D for the CIE colour locus coordinates 146 as a function of the operating period 134 for the change in the colour locus coordinates ΔCx 148 and ΔCy 150. While the colour locus coordinate Cy 150 does not change during operation, a significant shift in the colour locus can occur in the case of the colour locus coordinate Cx 148 as a result of the differential colour locus ageing (illustrated: ΔCx 148=−0.017; ΔCy 150=0). A visible colour shift from the warm-white colour locus of the white OLED can be brought about as a result. During the ageing of a white OLED, therefore, a colour shift towards the blue becomes visible, i.e. a negative Cx change (FIG. 1D).

A correction of the colour ageing is possible if the component has a complex colour locus regulation (including colour sensor). The specification of a minimum colour locus shift can thus be complied with only with difficulty (permissible tolerances of the colour locus deviations 152, 154 are illustrated at the edge in FIG. 1D). As a result, the operating period of the white OLED can be reduced in addition to the reduction of the operating period on account of the ageing of the emitter layers 110, 112, 114 and/or a colour locus correction may be necessary.

In one conventional method, an OLED having a first OLED unit having the first emitter layer and the second emitter layer and a second OLED unit having the third emitter layer is used for colour locus regulation. By varying the current through the first OLED unit and the second OLED unit, it is possible to set a colour locus between the colour loci of the individual OLED units.

In direct current (DC) operation of a white OLED, a colour locus correction is only possible if the different emitter layers are driveable separately. This colour locus setting is conventionally realised with the aid of an OLED stacked monolithically in an inverted fashion and having two OLED units as described above. Three terminals and two voltage sources are required for a colour locus regulation in direct current operation (FIGS. 3A-3B).

In alternating current (AC) operation, a colour locus regulation can likewise be carried out. An OLED having OLED units stacked monolithically and electrically in antiparallel is conventionally used for this purpose. This has the advantage of managing with only two current contacts and only one current supply (FIGS. 4A-43). This conventional method is based on two OLED units being connected in antiparallel with one another. In this way, one OLED unit serves as a diode rectifier for the other OLED unit, that is to say that in alternating current operation only one OLED unit emits in the positive cycle (positive half-cycle) and only the other OLED unit emits in the negative cycle (negative half-cycle) of the current pulse. In this case, the OLED units can be stacked in the area alongside one another or one above another. If OLED units having different emitter layers are used as described above, in the CIE diagram it is possible set a colour locus between the colour loci of the individual OLED units by way of the AC current parameters, for example current pulse height or current pulse width.

On account of the differential ageing of the emitter layers of the different OLED units, however, the colour locus is not stable during direct current operation or alternating current operation. In order to stabilize the colour locus, in one conventional method, the signal from an additional colour sensor in the beam path of the OLED units is used to report the instantaneous colour information back to the current source. In the case of a colour locus deviation, the operating parameters of the OLED units are corrected according to the measured signal of the colour sensor. In various embodiments, an optoelectronic component device and a method for operating an optoelectronic component are provided which make it possible to operate an OLED without a colour sensor with an at least reduced colour locus deviation during operation.

In various embodiments, an optoelectronic component device is provided, the optoelectronic component device including: an optoelectronic component and a control device for driving the optoelectronic component; wherein the optoelectronic component includes a first optically active structure and a second optically active structure, wherein the first optically active structure is designed for emitting a first electromagnetic radiation and ages in accordance with a first ageing function during operation; and wherein the second optically active structure is designed for emitting a second electromagnetic radiation and ages in accordance with a second ageing function during operation; wherein the optoelectronic component is formed in such a way that at least the first electromagnetic radiation is emitted in a first operating mode and at least the second electromagnetic radiation is emitted in a second operating mode; wherein the control device is designed to drive the optoelectronic component in a predefined driving interval partly in the first operating mode and partly in the second operating mode so as to reduce the difference between first ageing function and second ageing function during the operation of the optoelectronic component device.

In one configuration, the optoelectronic component can be driveable in a predefined driving interval partly in the first operating mode and partly in the second operating mode. As a result, a third electromagnetic radiation is emitted in a driving interval. The difference between first ageing function and second ageing function is thus reduced during the emission of the third electromagnetic radiation. As a result, the properties of the third electromagnetic radiation which are dependent on the ageing of the optoelectronic component device can be stable during the operation of the optoelectronic component device. The reason why a third electromagnetic radiation is perceived instead of the first electromagnetic radiation and the second electromagnetic radiation is the inertia of the human eye. If a driving interval falls below a specific duration, i.e. upon a driving frequency being exceeded, only the mixture of first electromagnetic radiation and second electromagnetic radiation is visible to the human eye. The mixture of the first electromagnetic radiation and second electromagnetic radiation is designated as third electromagnetic radiation.

In one configuration, the optoelectronic component can be formed in such a way that the first ageing function and the second ageing function have an approximately identical ageing coefficient.

In one configuration, the first optically active structure can be formed in such a way that the first electromagnetic radiation is a blue light.

In one configuration, the second optically active structure can be formed in such a way that the second electromagnetic radiation is a yellow light or a green-red light.

In other words: In one configuration, the first optically active structure can be formed in such a way that the first electromagnetic radiation is a blue light and the second optically active structure can be formed in such a way that the second electromagnetic radiation is a yellow light or a green-red light. A white light can be emitted or perceived as third electromagnetic radiation, that is to say as electromagnetic radiation of a driving interval.

In one configuration, the control device can be formed in such a way that the third electromagnetic radiation is a white light, for example having a correlated colour temperature in a range of 500 K to 11 000 K.

In one configuration, the control device may include an electrical energy source or can be electrically connected to an electrical energy source, wherein the electrical energy source provides the electrical energy for the first operating mode and for the second operating mode.

In one configuration, the electrical energy source can provide an AC current and/or an AC voltage for the first operating mode and/or for the second operating mode.

In one configuration, at least one property of the third electromagnetic radiation can be formed by means of the amplitude and/or the frequency of the AC current and/or the AC voltage.

In one configuration, the AC current can have a DC current proportion, or the AC voltage can have a DC voltage proportion.

In one configuration, the AC current and/or the AC voltage may have a frequency of greater than approximately 30 Hz.

In one configuration, the control device may be formed in such a way as to drive the first optically active structure in the first operating mode with a first voltage profile and to drive the second optically active structure in the second operating mode with a second voltage profile, which is different from the first voltage profile.

In one configuration, the control device may be formed in such a way that the first voltage profile has at least one non-linear first range.

In one configuration, the control device may be formed in such a way that the first range has at least one of the following shapes or a mixed shape of one of the following shapes: a pulse, a sine half-cycle, a rectangle, a triangle, a saw tooth.

In one configuration, the control device may be formed in such a way that the second voltage profile is formed as direct current operation.

In one configuration, the control device may be formed in such a way that a constant direct current is provided in direct current operation.

In one configuration, the control device may be formed in such a way that the second voltage profile has a non-linear second range.

In one configuration, the control device may be formed in such a way that the second range has at least one of the following shapes or a mixed shape of one of the following shapes: a pulse, a sine half-cycle, a rectangle, a triangle, a saw tooth.

In one configuration, the control device may be formed in such a way that the optoelectronic component is operated with a first half-cycle and a second half-cycle in alternating current operation.

In one configuration, the control device may be formed in such a way that a transition from first operating mode to second operating mode takes place with the transition from first half-cycle to second half-cycle.

In one configuration, the control device may be formed in such a way that the first half-cycle and the second half-cycle have different current directions.

In one configuration, the control device may be formed in such a way that the first half-cycle and the second half-cycle are formed asymmetrically.

In one configuration, the control device may be formed in such a way that the first half-cycle is formed asymmetrically with respect to the second half-cycle.

In one configuration, the control device may be formed in such a way that the first half-cycle has a different maximum absolute value of the amplitude compared with the second half-cycle.

In one configuration, the control device may be formed in such a way that the first operating mode has at least one first half-cycle and the second operating mode has at least one second half-cycle.

In one configuration, the control device may be formed in such a way that the first half-cycle has a different pulse width compared with the second half-cycle.

In one configuration, the control device may be formed in such a way that the first half-cycle has a greater duty ratio than the second half-cycle.

In one configuration, the control device may be formed in such a way that the difference in the ageing function is less than a threshold value.

In one configuration, the control device may be formed in such a way that the threshold value is a function with respect to the differential colour locus ageing of the first optically active structure and of the second optically active structure.

In one configuration, the control device may be formed in such a way that the threshold value has an absolute value such that the colour locus shift linked by the differential colour locus ageing is less than 0.02 in Cx and/or Cy in a CIE standard chromaticity diagram.

In various embodiments, a method for operating an optoelectronic component is provided, wherein the optoelectronic component includes a first optically active structure and a second optically active structure, wherein the first optically active structure is designed for emitting a first electromagnetic radiation and ages in accordance with a first ageing function during operation; and wherein the second optically active structure is designed for emitting a second electromagnetic radiation and ages in accordance with a second ageing function during operation; wherein the optoelectronic component is formed in such a way that at least the first electromagnetic radiation is emitted in a first operating mode and at least the second electromagnetic radiation is emitted in a second operating mode; the method including: driving the optoelectronic component in a predefined driving interval partly in the first operating mode and partly in the second operating mode in such a way as to reduce the difference between first ageing function and second ageing function during the operation of the optoelectronic component.

In one configuration, in the predefined driving interval a third electromagnetic radiation may be emitted and/or perceived and the optoelectronic component can be driven in such a way as to reduce the difference between first ageing function and second ageing function during the emission of the third electromagnetic radiation.

In one configuration of the method, the optoelectronic component may be driven in such a way that the first optically active structure and the second optically active structure simultaneously emit electromagnetic radiation. In other words: the optoelectronic component can be formed and driven in such a way that it can be operated simultaneously in the first operating mode and in the second operating mode.

In one configuration of the method, the optoelectronic component may be formed in such a way that the first ageing function and the second ageing function have an approximately identical ageing coefficient. In other words: the first ageing function and the second ageing function can be described by a stretched exponential decay. The exponent of the ageing function can have an approximately identical power in the case of the first ageing function and the second ageing function (see below). The identical power can also be designated as ageing coefficient.

In one configuration of the method, the first optically active structure may be formed in such a way that the first electromagnetic radiation is a blue light.

In one configuration of the method, the second optically active structure may be formed in such a way that the second electromagnetic radiation is a yellow light or a green-red light.

In one configuration of the method, the optoelectronic component may be driven in such a way that the mixture of first electromagnetic radiation and second electromagnetic radiation in a driving interval is a white light, for example having a (correlated) colour temperature in a range of 500 K to 11 000 K. In other words: the third electromagnetic radiation can be a white light, for example having a (correlated) colour temperature in a range of 500 K to 11 000 K.

In one configuration of the method, the optoelectronic component may be electrically connected to an electrical energy source, wherein the electrical energy source provides the electrical energy for the first operating mode and for the second operating mode.

In one configuration of the method, the electrical energy source may provide an AC current and/or an AC voltage.

In one configuration of the method, at least one property of the third electromagnetic radiation may be formed by the amplitude and/or the frequency of an AC current and/or an AC voltage.

In one configuration of the method, the AC current may have a DC current proportion, or the AC voltage can have a DC voltage proportion.

In one configuration of the method, the AC current and/or the AC voltage may have a frequency of greater than approximately 30 Hz.

In one configuration of the method, the first operating mode may include driving the first optically active structure with a first voltage profile and the second operating mode may include driving the second optically active structure with a second voltage profile, which is different from the first voltage profile.

In one configuration of the method, the first voltage profile may have at least one non-linear first range.

In one configuration of the method, the first range may have at least one of the following shapes or a mixed shape of one of the following shapes: a pulse, a sine half-cycle, a rectangle, a triangle, a saw tooth.

In one configuration of the method, the second voltage profile may be formed as direct current operation.

In one configuration of the method, a constant direct current may be provided in direct current operation.

In one configuration of the method, the second operating mode may include driving the second optically active structure with a non-linear voltage profile.

In one configuration of the method, the second voltage profile may have a non-linear second range.

In one configuration of the method, the second range may include at least one of the following shapes or a mixed shape of one of the following shapes: a pulse, a sine half-cycle, a rectangle, a triangle, a saw tooth.

In one configuration of the method, the optoelectronic component may be operated with a first half-cycle and a second half-cycle in alternating current operation.

In one configuration of the method, the non-linear second range, in a predefined driving interval, may have a duty ratio in a range of approximately 0 to approximately 4.

In one configuration of the method, the optoelectronic component may be formed in such a way that a transition from first operating mode to second operating mode takes place with the transition from first half-cycle to second half-cycle.

In one configuration of the method, the first half-cycle and the second half-cycle may have different current directions.

In one configuration of the method, the first half-cycle and the second half-cycle may be formed asymmetrically.

In one configuration of the method, the first half-cycle may be formed asymmetrically with respect to the second half-cycle. For example not point-symmetrically or mirror-symmetrically with respect to the current profile or the voltage profile regarding the transition from first half-cycle to second half-cycle.

In one configuration of the method, the first half-cycle may have a different maximum absolute value of the amplitude compared with the second half-cycle.

In one configuration of the method, the first operating mode may have at least one first half-cycle and the second operating mode may have at least one second half-cycle. In other words: an operating mode can have one or a plurality of half-cycles, wherein a half-cycle can have a periodic or random sequence of voltage profiles having an identical current direction. By way of example, the first operating mode may have a first first half-cycle and a second first half-cycle. The first first half-cycle and the second first half-cycle may be sine half-cycles, for example. The sine half-cycles of the first first half-cycle and the second first half-cycle may have different amplitudes and pulse widths, however.

In one configuration of the method, the first half-cycle may have a different pulse width compared with the second half-cycle.

In one configuration of the method, the first half-cycle may have a greater duty ratio than the second half-cycle.

In one configuration of the method, the difference in the ageing function may be less than a threshold value.

In one configuration of the method, the threshold value may be a function with respect to the differential colour locus ageing of the first optically active structure and of the second optically active structure.

In one configuration of the method, the threshold value may have an absolute value such that the colour locus shift linked by means of the differential colour locus ageing is less than 0.02 in Cx and/or Cy in a CIE standard chromaticity diagram.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIGS. 1A-1D show schematic illustrations concerning an optoelectronic component device;

FIG. 2 shows a schematic illustration of an optoelectronic component in accordance with various embodiments;

FIGS. 3A, 3B show schematic illustrations of one embodiment of an optoelectronic component;

FIGS. 4A, 4B show schematic illustrations of one embodiment of an optoelectronic component;

FIGS. 5A, 5B show schematic illustrations of the alternating current operation of an optoelectronic component in accordance with various embodiments; and

FIGS. 6A-6C show schematic illustrations concerning an optoelectronic component during operation in accordance with various embodiments.

### DETAILED DESCRIPTION

In the following detailed description, reference is made to the accompanying drawings, which form part of this description and show for illustration purposes specific embodiments in which the invention can be implemented. In this regard, direction terminology such as, for instance, “at the top”, “at the bottom”, “at the front”, “at the back”, “front”, “rear”, etc. is used with respect to the orientation of the figure(s) described. Since component parts of embodiments can be positioned in a number of different orientations, the direction terminology serves for illustration and is not restrictive in any way whatsoever. It goes without saying that other embodiments can be used and structural or logical changes can be made, without departing from the scope of protection of the present invention. It goes without saying that the features of the various embodiments described herein can be combined with one another, unless specifically indicated otherwise. Therefore, the following detailed description should not be interpreted in a restrictive sense, and the scope of protection of the present invention is defined by the appended claims.

In the context of this description, the terms “connected” and “coupled” are used to describe both a direct and an indirect connection and a direct or indirect coupling. In the figures, identical or similar elements are provided with identical reference signs, insofar as this is expedient.

In various embodiments, optoelectronic components are described, wherein an optoelectronic component includes an optically active region. The optically active region can absorb electromagnetic radiation and form a photocurrent therefrom, or emit electromagnetic radiation by means of a voltage applied to the optically active region. In various embodiments, the electromagnetic radiation can have a wavelength range including x-ray radiation, UV radiation (A-C), visible light and/or infrared radiation (A-C).

A planar optoelectronic component having two planar, optically active sides can be formed for example as transparent or translucent in the connection direction of the optically active sides, for example as a transparent or translucent organic light emitting diode. A planar optoelectronic component can also be designated as a plane optoelectronic component.

However, the optically active region can also have one planar optically active side and one planar optically inactive side, for example an organic light emitting diode designed as a top emitter or a bottom emitter. The optically inactive side can be transparent or translucent, for example, or can be provided with a mirror structure and/or an opaque substance or substance mixture, for example for heat distribution. The beam path of the optoelectronic component can be directed on one side, for example.

In the context of this description, providing electromagnetic radiation can be understood to mean emitting electromagnetic radiation. In other words: providing electromagnetic radiation can be understood as emitting electromagnetic radiation by means of a voltage applied to an optically active region.

In the context of this description, taking up electromagnetic radiation can be understood to mean absorbing electromagnetic radiation. In other words: taking up electromagnetic radiation can be understood to mean absorbing electromagnetic radiation and forming a photocurrent from the absorbed electromagnetic radiation.

In various configurations, an electromagnetic radiation emitting structure (optically active structure) can be an electromagnetic radiation emitting semiconductor structure and/or be formed as an electromagnetic radiation emitting diode, as an organic electromagnetic radiation emitting diode, as an electromagnetic radiation emitting transistor or as an organic electromagnetic radiation emitting transistor. The radiation can be for example light (in the visible range), UV radiation and/or infrared radiation. In this context, the electromagnetic radiation emitting component can be formed for example as a light emitting diode (LED), as an organic light emitting diode (OLED), as a light emitting transistor or as an organic light emitting transistor. In various configurations, the electromagnetic radiation emitting component can be part of an integrated circuit. Furthermore, a plurality of electromagnetic radiation emitting components can be provided, for example in a manner accommodated in a common housing.

In various embodiments, an optoelectronic structure can be formed as an organic light emitting diode (OLED) (electromagnetic radiation emitting structure), an organic field effect transistor (OFET) and/or an organic electronic system. The organic field effect transistor can be a so-called “all-OFET”, in which all the layers are organic. An optoelectronic structure may include an organic functional layer system, which is synonymously also designated as organic functional layer structure. The organic functional layer structure may include or be formed from an organic substance or an organic substance mixture which is formed for example for providing an electromagnetic radiation from an electric current provided.

The optically active time is the time in which an optically active structure emits electromagnetic radiation.

The optically inactive time is the time in which an optically active structure emits no electromagnetic radiation.

The duty ratio (MUX) specifies the ratio of the optically inactive time to the optically active time in a driving interval. By way of example, an optically active structure, given a duty ratio of 2 (MUX=2) per driving interval, is optically inactive (unenergized) for 50% of the time of the driving interval and emits an electromagnetic radiation in 50% of the time of the driving interval.

The optically active time can be determined for example by means of a mathematical convolution of the pulse widths and pulse repetition frequency in a driving interval.

The maximum pulse amplitude can be understood to be that location of a pulse of electromagnetic radiation at which the pulse has the highest luminance.

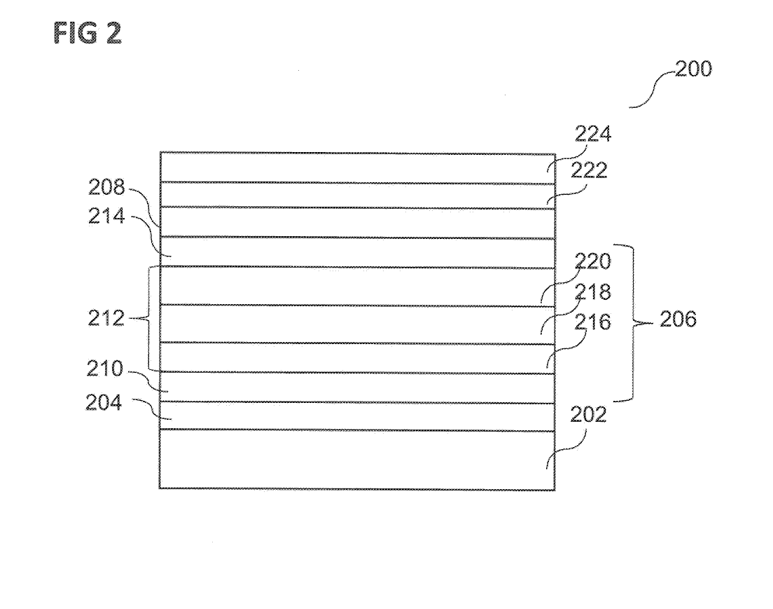

FIG. 2 shows a schematic cross-sectional view of an optoelectronic component in accordance with various embodiments.

The optoelectronic component 200 can be formed as an organic light emitting diode 200, an organic photodetector 200 or an organic solar cell.

An organic light emitting diode 200 can be formed as a top emitter or a bottom emitter. In the case of a bottom emitter, light is emitted from the electrically active region through the carrier. In the case of a top emitter, light is emitted from the top side of the electrically active region and not through the carrier.

A top emitter and/or bottom emitter can also be formed as optically transparent or optically translucent; by way of example, each of the layers or structures described below can be formed as transparent or translucent.

The optoelectronic component 200 may include a hermetically impermeable substrate, an active region and an encapsulation structure.

The hermetically impermeable substrate may include a carrier 202 and a first barrier layer 204.

The active region is an electrically active region and/or an optically active region. The active region is for example the region of the optoelectronic component 200 in which electric current for the operation of the optoelectronic component 200 flows and/or in which electromagnetic radiation is generated and/or absorbed.

The electrically active region 206 may include a first electrode 210, an organic functional layer structure 212 and a second electrode 214.

The organic functional layer structure 212 may include one, two or more functional layer structure units and one, two or more intermediate layer structure(s) between the layer structure units. The organic functional layer structure 212 may include for example a first organic functional layer structure unit 216, an intermediate layer structure 218 and a second organic functional layer structure unit 220.

The encapsulation structure may include a second barrier layer 208, a close connection layer 222 and a cover 224.

The carrier 202 may include or be formed from glass, quartz and/or a semiconductor material. Furthermore, the carrier may include or be formed from a plastics film or a laminate including one or including a plurality of plastics films. The plastic may include or be formed from one or a plurality of polyolefins (for example high or low density polyethylene (PE) or polypropylene (PP)). Furthermore, the plastic may include or be formed from polyvinyl chloride (PVC), polystyrene (PS), polyester and/or polycarbonate (PC), polyethylene terephthalate (PET), polyethersulphone (PES) and/or polyethylene naphthalate (PEN).

The carrier 202 may include or be formed from a metal, for example copper, silver, gold, platinum, iron, for example a metal compound, for example steel.

The carrier 202 can be embodied as opaque, translucent or even transparent.

The carrier 202 can be a part of a mirror structure or form the latter.

The carrier 202 can have a mechanically rigid region and/or a mechanically flexible region or be formed in this way, for example as a film.

The carrier 202 can be formed as a waveguide for electromagnetic radiation, for example can be transparent or translucent with respect to the emitted or absorbed electromagnetic radiation of the optoelectronic component 200.

The first barrier layer 204 may include or be formed from one of the following materials: aluminium oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminium-doped zinc oxide, poly(p-phenylene terephthalamide), nylon 66, and mixtures and alloys thereof.

The first barrier layer 204 can be formed by means of one of the following methods: an atomic layer deposition (ALD) method, for example a plasma enhanced atomic layer deposition (PEALD) method or a plasmaless atomic layer deposition (PLALD) method; a chemical vapour deposition (CVD) method, for example a plasma enhanced chemical vapour deposition (PECVD) method or a plasmaless chemical vapour deposition (PLCVD) method; or alternatively by means of other suitable deposition methods.

In the case of a first barrier layer 204 including a plurality of partial layers, all the partial layers can be formed by means of an atomic layer deposition method. A layer sequence including only ALD layers can also be designated as a “nanolaminate”.

In the case of a first barrier layer 204 including a plurality of partial layers, one or a plurality of partial layers of the first barrier layer 204 can be deposited by means of a different deposition method than an atomic layer deposition method, for example by means of a vapour deposition method.

The first barrier layer 204 can have a layer thickness of approximately 0.1 nm (one atomic layer) to approximately 1000 nm, for example a layer thickness of approximately 10 nm to approximately 100 nm in accordance with one configuration, for example approximately 40 nm in accordance with one configuration.

The first barrier layer 204 may include one or a plurality of high refractive index materials, for example one or a plurality of materials having a high refractive index, for example having a refractive index of at least 2.

Furthermore, it should be pointed out that, in various embodiments, a first barrier layer 204 can also be entirely dispensed with, for example for the case where the carrier 202 is formed in a hermetically impermeable fashion, for example includes or is formed from glass, metal, metal oxide.

The first electrode 210 can be formed as an anode or as a cathode.

The first electrode 210 may include or be formed from one of the following electrically conductive materials: a metal; a transparent conductive oxide (TCO); a network composed of metallic nanowires and nanoparticles, for example composed of Ag, which are combined with conductive polymers, for example; a network composed of carbon nanotubes which are combined with conductive polymers, for example; graphene particles and graphene layers; a network composed of semiconducting nanowires; an electrically conductive polymer; a transition metal oxide; and/or the composites thereof. The first electrode 210 composed of a metal or including a metal may include or be formed from one of the following materials: Ag, Pt, Au, Mg, Al, Ba, In, Ca, Sm or Li, and compounds, combinations or alloys of these materials. The first electrode 210 may include as transparent conductive oxide one of the following materials: for example metal oxides: for example zinc oxide, tin oxide, cadmium oxide, titanium oxide, indium oxide, or indium tin oxide (ITO). Alongside binary metal-oxygen compounds, such as, for example, ZnO, SnO₂, or In₂O₃, ternary metal-oxygen compounds, such as, for example, AlZnO, Zn₂SnO₄, CdSnO₃, ZnSnO₃, MgIn₂O₄, GaInO₃, Zn₂In₂O₅ or In₄Sn₃O₁₂, or mixtures of different transparent conductive oxides also belong to the group of TCOs and can be used in various embodiments. Furthermore, the TCOs do not necessarily correspond to a stoichiometric composition and can furthermore be p-doped or n-doped or be hole-conducting (p-TCO), or electron-conducting (n-TCO).

The first electrode 210 may include a layer or a layer stack of a plurality of layers of the same material or different materials. The first electrode 210 can be formed by a layer stack of a combination of a layer of a metal on a layer of a TCO, or vice versa. One example is a silver layer applied on an indium tin oxide layer (ITO) (Ag on ITO) or ITO-Ag-ITO multilayers.

The first electrode 210 can have for example a layer thickness in a range of 10 nm to 500 nm, for example of less than 25 nm to 250 nm, for example of 50 nm to 100 nm.

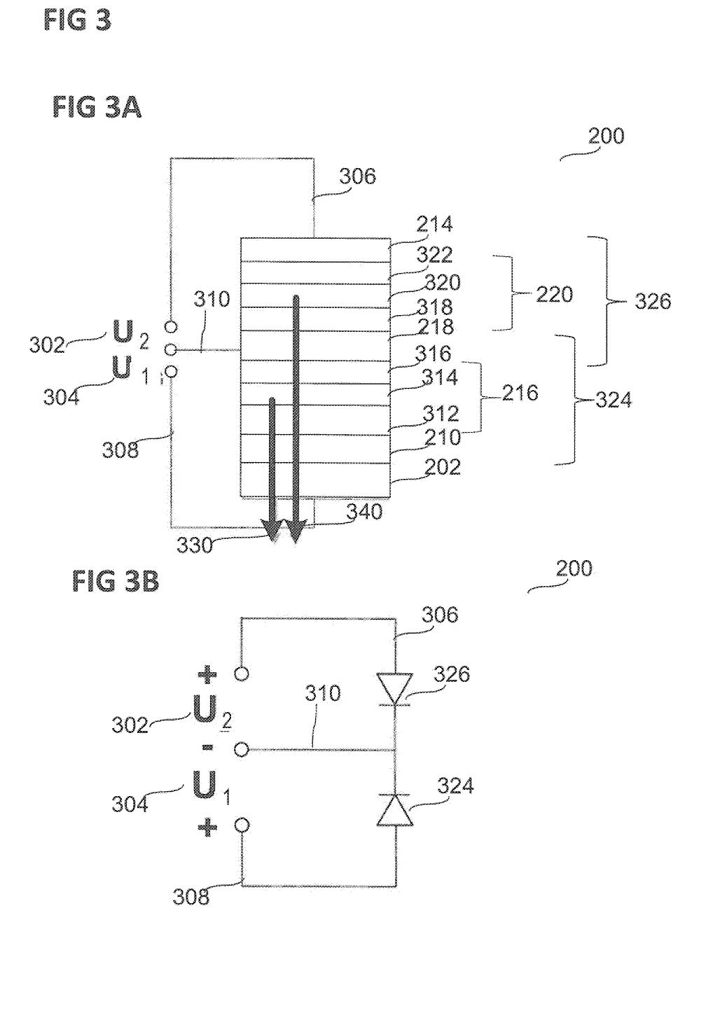

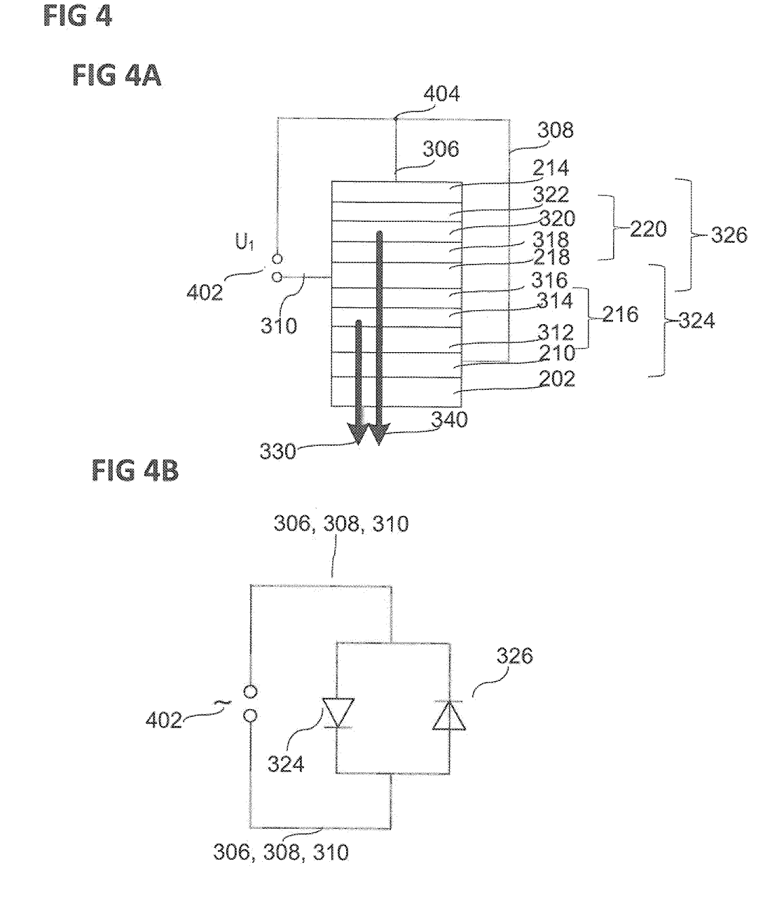

The first electrode 210 can have a first electrical terminal, to which a first electrical potential can be applied. The first electrical potential can be provided by an energy source (see FIGS. 3A-3B, 4A-4B), for example a current source or a voltage source. Alternatively, the first electrical potential can be applied to an electrically conductive carrier 202 and the first electrode 210 can be electrically supplied indirectly through the carrier 202. The first electrical potential can be for example the ground potential or some other predefined reference potential.

FIG. 2 illustrates an optoelectronic component 200 including a first organic functional layer structure unit 216 and a second organic functional layer structure unit 220. In various embodiments, however, the organic functional layer structure 212 may also include more than two organic functional layer structures, for example 3, 4, 5, 6, 7, 8, 9, 10, or even more, for example 15 or more, for example 70.

The first organic functional layer structure unit 216 and the optionally further organic functional layer structures may be formed identically or differently, for example include an identical or different emitter material. The second organic functional layer structure unit 220, or the further organic functional layer structure units can be formed like one of the below-described configurations of the first organic functional layer structure unit 216.

The first organic functional layer structure unit 216 may include a hole injection layer, a hole transport layer, an emitter layer, an electron transport layer and an electron injection layer (also see description of FIGS. 3A-3B, 4A-4B).

In an organic functional layer structure unit 212, one or a plurality of the layers mentioned can be provided, wherein identical layers can have a physical contact, can be only electrically connected to one another or can even be formed in a manner electrically insulated from one another, for example can be arranged alongside one another. Individual layers of the layers mentioned can be optional.

A hole injection layer can be formed on or above the first electrode 210. The hole injection layer may include or be formed from one or a plurality of the following materials: HAT-CN, Cu(I)pFBz, MoOₓ, WOₓ, VOₓ, ReOₓ, F4-TCNQ, NDP-2, NDP-9, Bi(III)pFBz, F16CuPc; NPB (N,N′-bis(naphthalen-1-yl)-N,N′-bis(phenyl)benzidine); beta-NPB N,N′-bis(naphthalen-2-yl)-N,N′-bis(phenyl)benzidine); TPD (N,N′-bis(3-methylphenyl)-N,N′-bis(phenyl)benzidine); Spiro TPD (N,N′-bis(3-methylphenyl)-N,N′-bis(phenyl)benzidine); spiro-NPB (N,N′-bis(naphthalen-1-yl)-N,N′-bis(phenyl)spiro); DMFL-TPD N,N′-bis(3-methylphenyl)-N,N′-bis(phenyl)-9,9-dimethylfluorene); DMFL-NPB (N,N′-bis(naphthalen-1-yl)-N,N′-bis(phenyl)-9,9-dimethylfluorene); DPLF-TPD (N,N′-bis(3-methylphenyl)-N,N′-bis(phenyl)-9,9-diphenylfluorene); DPFL-NPB (N,N′-bis(naphthalen-1-yl)-N,N′-bis(phenyl)-9,9-diphenylfluorene); Spiro-TAD (2,2′,7,7′-tetrakis(n,n-diphenylamino)-9,9′-spirobifluorene); 9, 9-bis[4-(N,N-bisphenyl-4-yl-amino)phenyl]-9H-fluorene; 9, 9-bis[4-(N,N-bis-napthalen-2-yl-amino)phenyl]-9H-fluorene; 9, 9-bis[4-(N,N′-bis-naphthalen-2-yl-N,N′-bisphenylamino)phenyl]-9H-fluorine; N,N′-bis(phenanthren-9-yl)-N,N′-bis(phenyl)benzidine; 2,7-bis[N,N-bis(9,9-spirobifluoren-2-yl)amino)-9,9-spirobifluorene; 2,2′-bis[N,N-bis(biphenyl-4-yl)amino]9,9-spirobifluorene; 2,2′-bis(N,N-diphenylamino)]9,9-spirobifluorene; di-[4-(N,N-di-tolylamino)phenyl]cyclohexane; 2,2′,7,7′-tetra(N,N-di-tolyl)aminospirobifluorene; and/or N,N,N′,N′-tetranaphthalen-2-ylbenzidine.

The hole injection layer can have a layer thickness in a range of approximately 10 nm to approximately 1000 nm, for example in a range of approximately 30 nm to approximately 300 nm, for example in a range of approximately 50 nm to approximately 200 nm.

A hole transport layer can be formed on or above the hole injection layer. The hole transport layer may include or be formed from one or a plurality of the following materials: NPB (N,N′-bis(naphthalen-1-yl)-N,N′-bis(phenyl)benzidine); beta-NPB N,N′-bis(naphthalen-2-yl)-N,N′-bis(phenyl)-benzidine); TPD (N,N′-bis(3-methylphenyl)-N,N′-bis(phen-yl)benzidine); Spiro TPD (N,N′-bis(3-methylphenyl)-N,N′-bis(phenyl)benzidine); spiro-NPB (N,N′-bis(naphthalen-1-yl)-N,N′-bis(phenyl)spiro); DMFL-TPD N,N′-bis(3-methylphenyl)-N,N′-bis(phenyl)-9,9-dimethylfluorene); DMFL-NPB (N,N′-bis(naphthalen-1-yl)-N,N′-bis(phenyl)-9,9-dimethylfluorene); DPFL-TPD (N,N′-bis(3-methylphenyl)-N,N′-bis(phenyl)-9,9-diphenylfluorene); DPFL-NPB (N,N′-bis(naphthalen-1-yl)-N,N′-bis(phenyl)-9,9-diphenylfluorene); Spiro-TAD (2,2′,7,7′-tetrakis(n,n-diphenylamino)-9,9′-spirobifluorene); 9,9-bis[4-(N,N-bisbiphenyl-4-yl-amino)phenyl]-9H-fluorene; 9,9-bis[4-(N,N′-bisnaphthalen-2-ylamino)phenyl]-9H-fluorene; 9,9-bis[4-(N,N′-bisnaphthalen-2-yl-N,N′-bisphenylamino)phenyl]-9H-fluorine; N,N′-bis(phenanthren-9-yl)-N,N′-bis(phenyl)benzidine; 2,7-bis[N,N-bis(9,9-spirobifluoren-2-yl)amino]-9,9-spirobifluorene; 2,2′-bis[N,N-bis(biphenyl-4-yl)amino]-9,9-spirobifluorene; 2,2′-bis(N,N-diphenylamino)9,9-spirobifluorene; di-[4-(N,N-ditolyl-amino)phenyl]cyclohexane; 2,2′,7,7′-tetra(N,N-di-ditolyl)aminospirobifluorene; and N,N,N′,N′-tetranaphthalen-2-yl-benzidine, a tertiary amine, a carbazole derivative, a conductive polyaniline and/or polyethylene dioxythiophene.

The hole transport layer can have a layer thickness in a range of approximately 5 nm to approximately 50 nm, for example in a range of approximately 10 nm to approximately 30 nm, for example approximately 20 nm.

An emitter layer can be formed on or above the hole transport layer. Each of the organic functional layer structure units 216, 220 may include in each case one or a plurality of emitter layers, for example including fluorescent and/or phosphorescent emitters.

An emitter layer may include or be formed from organic polymers, organic oligomers, organic monomers, organic small, non-polymeric molecules (“small molecules”) or a combination of these materials.

The optoelectronic component 200 may include or be formed from one or a plurality of the following materials in an emitter layer: organic or organometallic compounds such as derivatives of polyfluorene, polythiophene and polyphenylene (e.g. 2- or 2,5-substituted poly-p-phenylene vinylene) and metal complexes, for example iridium complexes such as blue phosphorescent FIrPic (bis(3,5-difluoro-2-(2-pyridyl)phenyl(2-carboxypyridyl)iridium III), green phosphorescent Ir(ppy)₃ (tris(2-phenylpyridine)iridium III), red phosphorescent Ru (dtb-bpy)₃*2(PF₆) (tris[4,4′-di-tert-butyl-(2,2′)-bipyridine]ruthenium(III) complex) and blue fluorescent DPAVBi (4,4-bis[4-(di-p-tolyl-amino)styryl]biphenyl), green fluorescent TTPA (9,10-bis[N,N-di(p-tolyl)amino]anthracene) and red fluorescent DCM2 (4-dicyanomethylene)-2-methyl-6-julolidyl-9-enyl-4H-pyran) as non-polymeric emitters.

Such non-polymeric emitters can be deposited for example by means of thermal evaporation. Furthermore, polymer emitters can be used which can be deposited for example by means of a wet-chemical method, such as, for example, a spin coating method.

The emitter materials can be embedded in a suitable manner in a matrix material, for example a technical ceramic or a polymer, for example an epoxy; or a silicone.

In various embodiments, the first emitter layer 218 can have a layer thickness in a range of approximately 5 nm to approximately 50 nm, for example in a range of approximately 10 nm to approximately 30 nm, for example approximately 20 nm.

The emitter layer may include emitter materials that emit in one colour or in different colours (for example blue and yellow or blue, green and red). Alternatively, the emitter layer may include a plurality of partial layers which emit light of different colours. By means of mixing the different colours, the emission of light having a white colour impression can result. Alternatively, provision can also be made for arranging a converter material in the beam path of the primary emission generated by said layers, which converter material at least partly absorbs the primary radiation and emits a secondary radiation having a different wavelength, such that a white colour impression results from a (not yet white) primary radiation by virtue of the combination of primary radiation and secondary radiation.

The organic functional layer structure unit 216 may include one or a plurality of emitter layers embodied as hole transport layer.

Furthermore, the organic functional layer structure unit 216 may include one or a plurality of emitter layers embodied as electron transport layer.

An electron transport layer can be formed, for example deposited, on or above the emitter layer.

The electron transport layer may include or be formed from one or a plurality of the following materials: NET-18; 2,2′,2″-(1,3,5-benzinetriyl)tris(1-phenyl-1-H-benzimidazole); 2-(4-biphenylyl)-5-(4-tert-butylphenyl)-1,3,4-oxadiazole, 2,9-dimethyl-4,7-diphenyl-1,10-phenanthroline (BCP); 8-hydroxyquinolinolato lithium; 4-(naphthalen-1-yl)-3,5-diphenyl-4H-1,2,4-triazole; 1,3-bis[2-(2,2′-bipyridin-6-yl)-1,3,4-oxadiazo-5-yl]benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolate)-4-(phenylphenolato)aluminium; 6,6′-bis[5-(biphenyl-4-yl)-1,3,4-oxadiazo-2-yl]-2,2′-bipyridyl; 2-phenyl-9,10-di(naphthalen-2-yl)anthracene; 2,7-bis[2-(2,2′-bipyridin-6-yl)-1,3,4-oxadiazo-5-yl]-9,9-dimethylfluorene; 1,3-bis[2-(4-tert-butylphenyl)-1,3,4-oxadiazo-5-yl]benzene; 2-(naphthalen-2-yl)-4,7-diphenyl-1,10-phenanthroline; 2,9-bis(naphthalen-2-yl)-4,7-diphenyl-1,10-phenanthroline; tris(2,4,6-trimethyl-3-(pyridin-3-yl)phenyl)borane; 1-methyl-2-(4-(naphthalen-2-yl)phenyl)-1H-imidazo[4,5-f][1,10]phenanthroline; phenyl-dipyrenylphosphine oxide; naphthalenetetracarboxylic dianhydride or the imides thereof; perylenetetracarboxylic dianhydride or the imides thereof; and substances based on silols including a silacyclopentadiene unit.

The electron transport layer can have a layer thickness in a range of approximately 5 nm to approximately 50 nm, for example in a range of approximately 10 nm to approximately 30 nm, for example approximately 20 nm.

An electron injection layer can be formed on or above the electron transport layer. The electron injection layer may include or be formed from one or a plurality of the following materials: NDN-26, MgAg, Cs₂CO₃, Cs₃PO₄, Na, Ca, K, Mg, Cs, Li, LiF; 2,2′,2″-(1,3,5-benzinetriyl)tris(1-phenyl-1-H-benzimidazole); 2-(4-biphenylyl)-5-(4-tert-butylphenyl)-1,3,4-oxadiazole, 2,9-dimethyl-4,7-diphenyl-1,10-phenanthroline (BCP); 8-hydroxyquinolinolato lithium, 4-(naphthalen-1-yl)-3,5-diphenyl-4H-1,2,4-triazole; 1,3-bis[2-(2,2′-bipyridin-6-yl)-1,3,4-oxadiazo-5-yl]benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolate)-4-(phenylphenolato)aluminium; 6,6′-bis[5-(biphenyl-4-yl)-1,3,4-oxadiazo-2-yl]-2,2′-bipyridyl; 2-phenyl-9,10-di(naphthalen-2-yl)anthracene; 2,7-bis[2-(2,2′-bipyridin-6-yl)-1,3,4-oxadiazo-5-yl]-9,9-dimethylfluorene; 1,3-bis[2-(4-tert-butylphenyl)-1,3,4-oxadiazo-5-yl]benzene; 2-(naphthalen-2-yl)-4,7-diphenyl-1,10-phenanthroline; 2,9-bis(naphthalen-2-yl)-4,7-diphenyl-1,10-phenanthroline; tris(2,4,6-trimethyl-3-(pyridin-3-yl)phenyl)borane; 1-methyl-2-(4-(naphthalen-2-yl)phenyl)-1H-imidazo[4,5-f][1,10]phenanthroline; phenyldipyrenylphosphine oxide; naphthalenetetracarboxylic dianhydride or the imides thereof; perylenetetracarboxylic dianhydride or the imides thereof; and substances based on silols including a silacyclopentadiene unit.

The electron injection layer can have a layer thickness in a range of approximately 5 nm to approximately 200 nm, for example in a range of approximately 20 nm to approximately 50 nm, for example approximately 30 nm.

In the case of an organic functional layer structure 212 including two or more organic functional layer structure units 216, 220, the second organic functional layer structure unit 220 can be formed above or alongside the first functional layer structure units 216. An intermediate layer structure 218 can be formed electrically between the organic functional layer structure units 216, 220.

In various embodiments, the intermediate layer structure 218 can be formed as an intermediate electrode 218, for example in accordance with one of the configurations of the first electrode 210. An intermediate electrode 218 can be electrically connected to an external voltage source. The external voltage source can provide a third electrical potential, for example, at the intermediate electrode 218. However, the intermediate electrode 218 can also have no external electrical connection, for example by the intermediate electrode having a floating electrical potential.

In various embodiments, the intermediate layer structure 218 can be formed as a charge generating layer structure 218 (charge generation layer CGL). A charge generating layer structure 218 may include one or a plurality of electron-conducting charge generating layer(s) and one or a plurality of hole-conducting charge generating layer(s). The electron-conducting charge generating layer(s) and the hole-conducting charge generating layer(s) can be formed in each case from an intrinsically conductive substance or a dopant in a matrix.

The charge generating layer structure 218 should be formed, with respect to the energy levels of the electron-conducting charge generating layer(s) and the hole-conducting charge generating layer(s), in such a way that electron and hole can be separated at the interface between an electron-conducting charge generating layer and a hole-conducting charge generating layer. The charge generating layer structure 218 can furthermore have a diffusion barrier between adjacent layers.

Each organic functional layer structure unit 216, 220 can have for example a layer thickness of a maximum of approximately 3 μm, for example a layer thickness of a maximum of approximately 1 μm, for example a layer thickness of a maximum of approximately 300 nm.

The optoelectronic component 200 may optionally include further organic functional layers, for example arranged on or above the one or the plurality of emitter layers or on or above the electron transport layer(s). The further organic functional layers can be for example internal or external coupling-in/coupling-out structures that further improve the functionality and thus the efficiency of the optoelectronic component 200.

The second electrode 214 can be formed on or above the organic functional layer structure 212 or, if appropriate, on or above the one or the plurality of further organic functional layer structures and/or organic functional layers.

The second electrode 214 can be formed in accordance with one of the configurations of the first electrode 210, wherein the first electrode 210 and the second electrode 214 can be formed identically or differently. The second electrode 214 can be formed as an anode, that is to say as a hole-injecting electrode, or as a cathode, that is to say as an electron-injecting electrode.

The second electrode 214 can have a second electrical terminal, to which a second electrical potential can be applied. The second electrical potential can be provided by the same energy source as, or a different energy source than, the first electrical potential and/or the optional third electrical potential. The second electrical potential can be different than the first electrical potential and/or the optionally third electrical potential. The second electrical potential can have for example a value such that the difference with respect to the first electrical potential has a value in a range of approximately 1.5 V to approximately 20 V, for example a value in a range of approximately 2.5 V to approximately 15 V, for example a value in a range of approximately 3 V to approximately 12 V.

The second barrier layer 208 can be formed on the second electrode 214.

The second barrier layer 208 can also be referred to as thin film encapsulation (TFE). The second barrier layer 208 can be formed in accordance with one of the configurations of the first barrier layer 204.

Furthermore, it should be pointed out that, in various embodiments, a second barrier layer 208 can also be entirely dispensed with. In such a configuration, the optoelectronic component 200 may include for example a further encapsulation structure, as a result of which a second barrier layer 208 can become optional, for example a cover 224, for example a cavity glass encapsulation or metallic encapsulation.

Furthermore, in various embodiments, in addition, one or a plurality of coupling-in/coupling-out layers can also be formed in the optoelectronic component 200, for example an external coupling-out film on or above the carrier 202 (not illustrated) or an internal coupling-out layer (not illustrated) in the layer cross section of the optoelectronic component 200. The coupling-in/coupling-out layer may include a matrix and scattering centres distributed therein, wherein the average refractive index of the coupling-in/coupling-out layer is greater or less than the average refractive index of the layer from which the electromagnetic radiation is provided. Furthermore, in various embodiments, in addition, one or a plurality of antireflection layers (for example combined with the second barrier layer 208) can be provided in the optoelectronic component 200.

In various embodiments, a close connection layer 222, for example composed of an adhesive or a lacquer, can be provided on or above the second barrier layer 208. By means of the close connection layer 222, a cover 224 can be closely connected, for example adhesively bonded, on the second barrier layer 208.

A close connection layer 222 composed of a transparent material may include for example particles which scatter electromagnetic radiation, for example light-scattering particles. As a result, the close connection layer 222 can act as a scattering layer and lead to a reduction or increase in the colour angle distortion and the coupling-out efficiency.

The light-scattering particles provided can be dielectric scattering particles, for example, composed of a metal oxide, for example, silicon oxide (SiO₂), zinc oxide (ZnO), zirconium oxide (ZrO₂), indium tin oxide (ITO) or indium zinc oxide (IZO), gallium oxide (Ga₂Oₓ), aluminium oxide, or titanium oxide. Other particles may also be suitable provided that they have a refractive index that is different than the effective refractive index of the matrix of the close connection layer 222, for example air bubbles, acrylate, or hollow glass beads. Furthermore, by way of example, metallic nanoparticles, metals such as gold, silver, iron nanoparticles, or the like can be provided as light-scattering particles.

The close connection layer 222 can have a layer thickness of greater than 1 μm, for example a layer thickness of a plurality of μm. In various embodiments, the close connection layer 222 may include or be a lamination adhesive.

The close connection layer 222 can be designed in such a way that it includes an adhesive having a refractive index that is less than the refractive index of the cover 224. Such an adhesive can be for example a low refractive index adhesive such as, for example, an acrylate having a refractive index of approximately 1.3. However, the adhesive can also be a high refractive index adhesive which for example includes high refractive index, non-scattering particles and has a layer-thickness-averaged refractive index that approximately corresponds to the average refractive index of the organic functional layer structure 212, for example in a range of approximately 1.7 to approximately 2.0. Furthermore, a plurality of different adhesives can be provided which form an adhesive layer sequence.

In various embodiments, between the second electrode 214 and the close connection layer 222, an electrically insulating layer (not shown) can also be or have been applied, for example SiN, for example having a layer thickness in a range of approximately 300 nm to approximately 1.5 μm, for example having a layer thickness in a range of approximately 500 nm to approximately 1 μm, in order to protect electrically unstable materials, during a wet-chemical process for example.

In various embodiments, a close connection layer 222 can be optional, for example if the cover 224 is formed directly on the second barrier layer 208, for example a cover 224 composed of glass that is formed by means of plasma spraying.

Furthermore, a so-called getter layer or getter structure, for example a laterally structured getter layer, can be arranged (not illustrated) on or above the electrically active region 206.

The getter layer may include or be formed from a material that absorbs and binds substances that are harmful to the electrically active region 206. A getter layer may include or be formed from a zeolite derivative, for example. The getter layer can be formed as translucent, transparent or opaque.

The getter layer can have a layer thickness of greater than approximately 1 μm, for example a layer thickness of a plurality of μm.

In various embodiments, the getter layer may include a lamination adhesive or be embedded in the close connection layer 222.

A cover 224 can be formed on or above the close connection layer 222. The cover 224 can be closely connected to the electrically active region 206 by means of the close connection layer 222 and can protect said region from harmful substances. The cover 224 can be for example a glass cover 224, a metal film cover 224 or a sealed plastics film cover 224. The glass cover 224 can be closely connected to the second barrier layer 208 or the electrically active region 206 for example by means of frit bonding (glass soldering/seal glass bonding) by means of a conventional glass solder in the geometric edge regions of the organic optoelectronic component 200.

The cover 224 and/or the close connection layer 222 can have a refractive index (for example at a wavelength of 633 nm) of 1.55.

FIGS. 3A, 3B show schematic illustrations of one embodiment of an optoelectronic component.

The optoelectronic component 200 can be formed in such a way that the first organic functional layer structure unit 216 and the second organic functional layer structure unit 220 have a common electrode by means of the intermediate layer structure 218. For this purpose, the intermediate layer structure 218 can be electrically connected to a third potential terminal 310 (indicated in FIG. 3A by means of the electrical connections to the voltage sources 302, 304).

In one embodiment, the optoelectronic component 200 includes an intermediate layer structure 218 between a first organic functional layer structure unit 216 and a second organic functional layer structure unit 220. The first electrode 210 is connected to a first electrical potential terminal 308 and the second electrode 214 is connected to a second electrical potential terminal 306 (indicated in FIG. 3A by means of the electrical connections to the voltage sources 302, 304).

The first organic functional layer structure unit 216 and the second organic functional layer structure unit 220 can be formed and energized in such a way that the charge carriers in the organic functional layer structure units 216, 220 have different current directions with respect to the intermediate layer structure 218. For this purpose, the intermediate layer structure 218 can be electrically connected to an earth potential, for example. In the case of organic functional layer structure units 216, 220 stacked one above another, the current directions in the organic functional layer structure units 216, 220 can thus be directed identically with respect to the intermediate layer structure 218. As a result, the first organic functional layer structure unit 216 and the second organic functional layer structure unit 220 can be energized electrically independently of one another (illustrated as a schematic circuit diagram in FIG. 3B).

The first organic functional layer structure unit 216 can be formed in such a way that it emits a first electromagnetic radiation 330 and the second organic functional layer structure unit 220 can be formed in such a way that it emits a second electromagnetic radiation 340.

The optoelectronic component 200 can be formed in such a way that the first electromagnetic radiation 330 and the second electromagnetic radiation 340 are emitted at least in a common direction, for example isotropically.

In the case of an optoelectronic component 200 formed as a bottom emitter, the intermediate layer structure 218, the first organic functional layer structure 216 and the carrier 202 can be formed as transparent or translucent at least with respect to the second electromagnetic radiation 340 (illustrated in FIG. 3A by means of the arrows 330, 340).

In the case of an optoelectronic component 200 formed as a top emitter, the intermediate layer structure 218, the second organic functional layer structure 220 and the encapsulation structure (see FIG. 2) can be formed as transparent or translucent at least with respect to the first electromagnetic radiation 330.

In the case of an optoelectronic component 200 formed as transparent or translucent, all layers of the optoelectronic component 200 (see the description of FIG. 2) can be formed as transparent or translucent at least with respect to the first electromagnetic radiation 330 and/or the second electromagnetic radiation 340.

In the image plane of the optoelectronic component 200, the mixture of first electromagnetic radiation 330 and second electromagnetic radiation 340 can form a third electromagnetic radiation. The properties of the third electromagnetic radiation can be varied proportionally between the properties of the first electromagnetic radiation 330 and the properties of the second electromagnetic radiation 340. The setting of the properties of the third electromagnetic radiation can be formed by means of a setting of the first electrical potential U1 across the first potential terminal 306 with the third potential terminal 310 with respect to a setting of the second electrical potential U2 across the second potential terminal 308 with the third potential terminal 310. One property of the third electromagnetic radiation is the colour locus, for example, which can be set thereby. This presupposes that the first electromagnetic radiation 330 and the second electromagnetic radiation 340 have a different colour locus.

The first electrical potential U1 can be designated as a first half-cycle during the operation of the optoelectronic component 200. The first electrical potential U1 can have a temporally variable profile, for example a non-linear profile or a discontinuity. Correspondingly, the second electrical potential U2 can also be designated as a second half-cycle.

The first organic functional layer structure unit 216 and the second organic functional layer structure unit 220 can be formed in accordance with an above-described configuration of an organic functional layer structure unit.

The structure between the first electrode 210 and the intermediate layer structure 218 inclusive can be designated as a first optically active structure 324 and the structure between the intermediate layer structure 218 and the second electrode 214 inclusive can be designated as a second optically active structure 326.

In one embodiment, the optoelectronic component 200 may include a glass carrier 202 with an ITO layer 210 as a first electrode 210. The first organic functional layer structure unit 216 may include a first hole injection layer 312, a first emitter layer 314 and a first electron injection layer 316. The second organic functional layer structure unit 220 may include a second electron injection layer 318, a second emitter layer 320 and a second hole injection layer 322. The hole injection layers 312, 322 and the electron injection layers 316, 318 can be formed in accordance with one of the configurations described in FIG. 2, for example in each case include an intrinsically conductive substance or a dopant in a matrix. The intermediate layer structure 218 is formed as an intermediate electrode 218, for example including MgAg. The second electrode may be formed like the intermediate electrode 218, for example include MgAg. The first emitter layer 314 and the second emitter layer 320 each include a dye for generating visible light. By way of example, the first emitter layer 314 may include a fluorescent dye and the second emitter layer 320 may include a phosphorescent dye; or the second emitter layer 320 may include a fluorescent dye and the first emitter layer 314 may include a phosphorescent dye. By way of example, the second emitter layer 320 may include a red-green phosphorescent dye and the first emitter layer 314 may include a blue fluorescent dye. In the second emitter layer 320, the red-green phosphorescent dye can be mixed or the red and green emitting dyes can be distributed in separate single-coloured partial layers.

On or above the second electrode 214 and thus on or above the electrically active region there can optionally also be an encapsulation structure, for example in accordance with one of the configurations mentioned above.

FIGS. 4A, 4B show schematic illustrations of one embodiment of an optoelectronic component.

In a departure from the configurations described above, the first electrode 210 and the second electrode 214 can be electrically connected to one another—illustrated by means of the node 404 in FIG. 4A.

The electrodes 306, 308, 310 are connected to a voltage source 402, which is formed as an AC voltage source. A driving interval may include at least one first half-cycle and at least one second half-cycle, wherein the first half-cycle and the second half-cycle are different, for example have a different current direction.

By means of the half-cycles having a different current direction of the AC voltage provided by the AC voltage source, the first organic functional layer structure unit 216 and the second organic functional layer structure unit 220 can be energized independently of one another. This is achieved by virtue of the fact that the first optically active structure 324 and the second optically active structure 326 are formed electrically in antiparallel with one another by means of the configuration of the optoelectronic component 200—illustrated schematically as a circuit diagram in FIG. 4B. As a result, in a first operating mode in the case of a first half-cycle the first organic functional layer structure unit 216 can emit a first electromagnetic radiation 330 and in a second operating mode in the case of a second half-cycle the second organic functional layer structure unit 220 can emit a second electromagnetic radiation 340. The optically active structures 324, 326 can thus alternately emit electromagnetic radiation 330, 340 and block the current. At frequencies above approximately 30 Hz, flicker can no longer be discernible to the human eye. The perceived third electromagnetic radiation is formed from averaging over time of the proportions of the first electromagnetic radiation 330 and of the second electromagnetic radiation 340 in a driving interval. The colour locus of the third electromagnetic radiation can be set by way of the AC current operating parameters of the voltage source 402. As a result, the optically active structures 324, 326 emitting different-coloured light 330, 340 can be driven differently, for example driven to different intensities. As a result, the respective contribution by the optically active structures 324, 326 to the third electromagnetic radiation can be varied. Furthermore, the stress and thus the ageing behaviour can be set by way of the duration and the height of the current pulses.

By way of example, in the case of a combination of a first optically active structure 324 emitting blue light 330 and a second optically active structure 326 emitting red-green light 340, a white light can be perceived as third electromagnetic radiation.

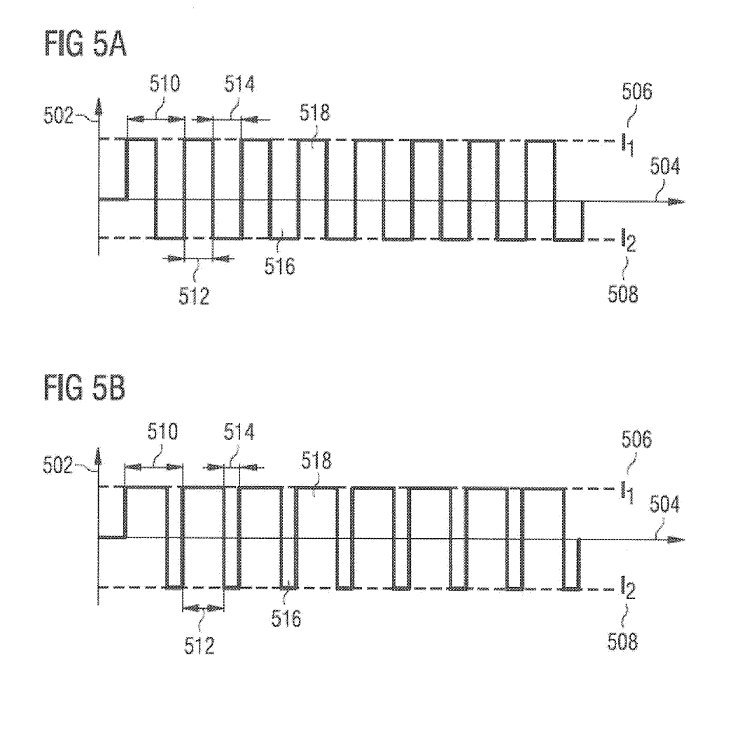

FIGS. 5A, 5B show schematic illustrations of an optoelectronic component in accordance with various embodiments.

The optoelectronic component 200 can be formed in such a way that the optically active structures 324, 326 can be energized independently of one another with two current sources (see description of FIG. 3A-3B) or in a manner dependent on one another with one AC current source (see description of FIG. 4A-4B).

In the case of a dependent energization, a plurality of optically active structures cannot be energized simultaneously. A dependent energization is present if the electrical energy source, for example the electrical ballast of the optoelectronic component, can provide only one DC current or only one AC current to two or more optically active structures simultaneously.

In the case of an independent energization, a plurality of optically active structures can be energized differently simultaneously. An independent energization is present if the ballast of the optoelectronic component can provide different DC currents or AC currents simultaneously at least to two optically active structures.

By way of example, in the case of an independent energization, the first optically active structure 324 can be energized with an AC current or DC current pulses, i.e. in the first operating mode, and the second optically active structure 326 can be energized with a DC current and/or AC current, i.e. in the second operating mode.

By way of example, in the case of a dependent energization, the first optically active structure 324 can be energized with the first half-cycle, i.e. in the first operating mode, and the second optically active structure 326 can be energized with the second half-cycle, i.e. in the second operating mode.

The properties of the third electromagnetic radiation can be set by means of the properties of the operating modes with respect to one another.

In the case of a dependent energization, the first operating mode and the second operating mode can be formed by means of a pulse width modulation, a pulse frequency modulation and/or a pulse amplitude modulation of the AC voltage.

The first half-cycle and/or the second half-cycle can have one of the following shapes or a mixed shape of one of the following shapes: a pulse, a sine half-cycle, a rectangle, a triangle, a saw tooth.

The shape of the first half-cycle and of the second half-cycle can be formed symmetrically or asymmetrically with respect to one another.

The first half-cycle can have a different maximum absolute value of the amplitude compared with the second half-cycle. By way of example, the maximum absolute value of the first half-cycle can be greater than the maximum absolute value of the second half-cycle—illustrated in FIG. 5A by means of the different current absolute values 506, 508 of the half-cycles by means of the arrows having the reference signs 512, 514. By way of example, the first half-cycle can have a different pulse width compared with the second half-cycle.

For energizing the optically active structures 324, 326, an AC current can have a DC current proportion; or an AC voltage can have a DC voltage proportion.

The first half-cycle can have a different pulse width compared with the second half-cycle—illustrated in FIG. 5B by means of the arrows of different lengths having the reference signs 512, 514. By way of example, the first half-cycle can have a smaller pulse width than the second half-cycle.

In a predefined driving interval 510, the temporal profile of the current intensity 502 of the first half-cycle 518 and of the second half-cycle 516 can be formed in a manner dependent on one another for forming the third electromagnetic radiation, for example in order to be able to set a predefined colour locus for the third electromagnetic radiation. As a result, a third electromagnetic radiation can be formed in a targeted manner after an averaging over time of the electromagnetic radiation emitted during the first half-cycle 518 and the second half-cycle 516 over a predefined driving interval 510. The temporal profile of the current intensity 502 can also be designated as a current intensity 502 as a function of time 504.

The third electromagnetic radiation is perceived as the electromagnetic radiation emitted on average over time during a predefined driving interval 510.

The properties of the third electromagnetic radiation can be set by means of the duty ratios and the maximum pulse amplitudes of the first electromagnetic radiation and of the second electromagnetic radiation.

FIG. 5A reveals a duty ratio of approximately 1 for the first electromagnetic radiation and the second electromagnetic radiation.

FIG. 5B reveals a duty ratio of approximately 0.33 for the first electromagnetic radiation and a duty ratio of approximately 3 for the second electromagnetic radiation.

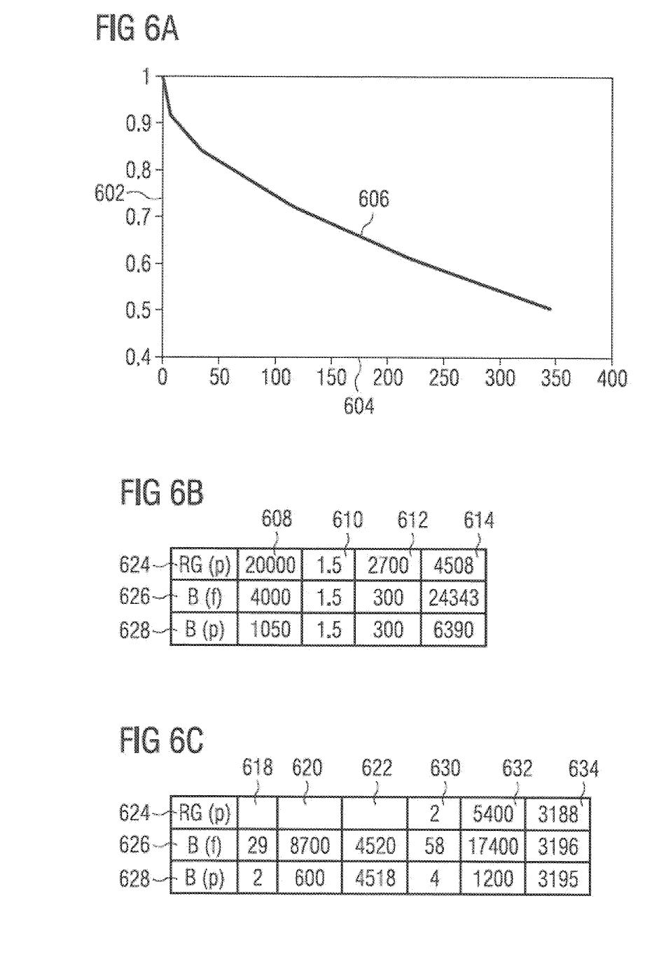

FIGS. 6A-6C show schematic illustrations concerning an optoelectronic component during operation in accordance with various embodiments.

The optoelectronic component can be formed in such a way that the relative decrease in the luminance 602 of the first optically active structure 324 and of the second optically active structure 326 can be described by a mathematical function, for example a stretched exponential decay.

A stretched exponential decay can be described mathematically as follows:

L/L₀αexp−(t/τᵢ)^{β} (I)

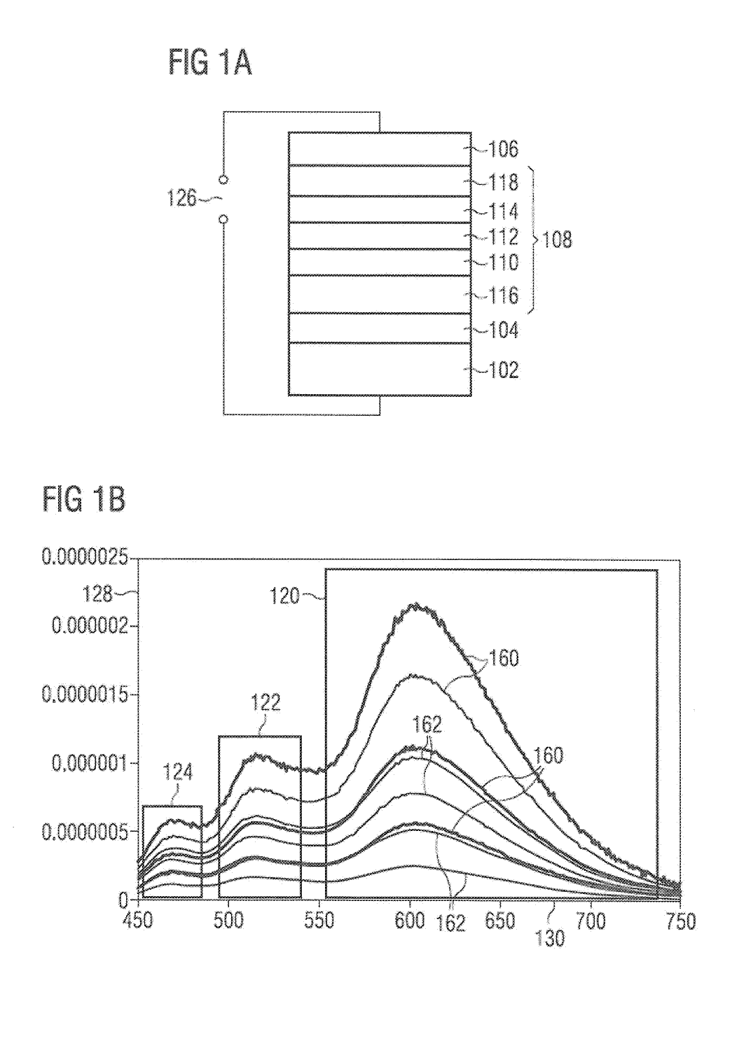

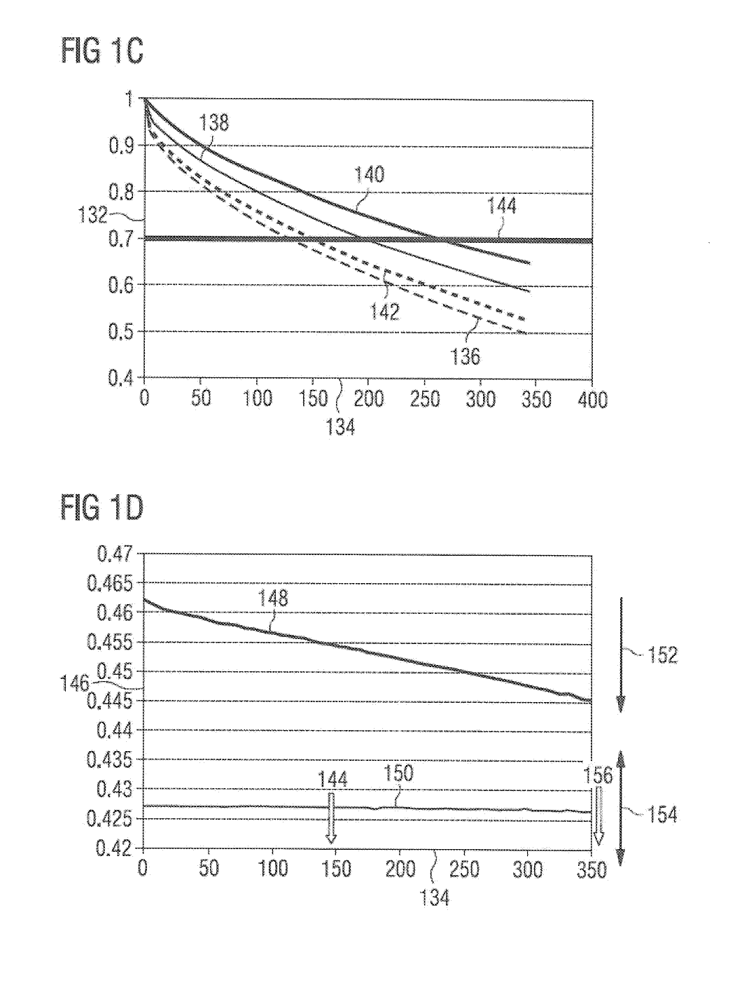

In this case, L is the luminance at the operating time t; L₀ is the initial luminance; τᵢ is a specific constant that is dependent on the emitter material of an optically active structure; and β is an ageing coefficient. The optoelectronic component 200 can be formed in such a way that each optically active structure has approximately the same ageing coefficient β. As a result, the optically active structures differ in their specific constant τᵢ (cf. FIG. 1C).

The functional relationship between the luminance and the operating period LT70 can be described by a non-linear function:

Lⁿ*LT70=constant. (II)

By means of the superlinear dependence of the luminance with n, the operating period decreases nonlinearly when the luminance increases. Here n is a real number greater than 1.

In the case of an optoelectronic component 200 having at least two optically active structures 324, 326, in order to form a specific third electromagnetic radiation, for example, the first optically active structure 324 has a higher operating period than the second optically active structure. The optoelectronic component 200 can be driven for forming the third electromagnetic radiation (see description of FIGS. 5A-5B) in such a way that the optically active structures 324 have approximately identical ageing. This is illustrated in FIG. 6A as superimposed ageing profiles 606 of the first optically active structure, of the second optically active structure and of the optoelectronic component.

An increase in the luminance of the first optically active structure leads with (II) to a superlinear reduction of the operating period of the first optically active structure. As a result, the ageing function of the first optically active structure can be matched to the ageing function of the second optically active structure. Moreover, by means of the increase in the luminance of the first optically active structure in the case of time averaging over a predefined driving interval (see description of FIGS. 5A-5B) this results in a relative increase in the proportion of the first electromagnetic radiation in the third electromagnetic radiation. This results in a shift in the properties of the third electromagnetic radiation towards the properties of the first electromagnetic radiation. However, the properties of the third electromagnetic radiation are intended to be maintained in the case of approximately identical ageing functions of the optically active structures. This is possible by reduction of the proportion of the first electromagnetic radiation with increased luminance in the third electromagnetic radiation on average over time in a predefined driving interval (see description of FIGS. 5A-5B). One possibility is forming the predefined driving interval of the driving of the optoelectronic component with pulses of first electromagnetic radiation. By means of the pulse height of the first electromagnetic radiation, with (II) the ageing function of the first optically active structure can be matched to the ageing function of the second electromagnetic radiation. The properties of the third electromagnetic radiation can be maintained by adaptation, for example reduction, of the pulse width and/or the pulse repetition frequency of pulses of the first electromagnetic radiation with respect to the averaging over time in a predefined driving interval.

In other words: since the lifetime is dependent superlinearly on the luminance, the lifetime decreases as the current pulse height increases. Dependent operation and independent operation of an optoelectronic component thus allow separate control of luminance and lifetime.

FIG. 6B and FIG. 6C show computational examples for an optoelectronic component having a first optically active structure 626, 628 and a second optically active structure 624. The optoelectronic component can be formed in accordance with one of the configurations described in FIG. 2 to FIG. 5. The first optically active structure 626, 628 and the second optically active structure 624 can be formed in such a way that the superlinear exponent n 610 of the luminance L—see (II)—has a value of approximately 1.5.

The second optically active structure 624 may include as emitter material a phosphorescent substance emitting red-green light or a phosphorescent substance mixture emitting red-green light. In direct current operation, the second optically active structure 624 at a luminance of 1000 cd/m² has a lifetime LT70 (1000 cd/m²) (reference sign 608) of 20 000 hours.

The first optically active structure may include as emitter material a fluorescent substance emitting blue light or a fluorescent substance mixture emitting blue light—illustrated in FIG. 6B by the reference sign 626. In direct current operation, the first optically active structure 626 including a fluorescent emitter at a luminance of 1000 cd/m² has a lifetime LT70 (1000 cd/m²) 608 of 4000 hours.

The first optically active structure may include as emitter material a phosphorescent substance emitting blue light or a phosphorescent substance mixture emitting blue light—illustrated in FIG. 6B by the reference sign 628. In direct current operation, the first optically active structure 628 including a phosphorescent emitter at a luminance of 1000 cd/m² has a lifetime LT70 (1000 cd/m²) 608 of 1050 hours.

In the exemplary calculations, with this optoelectronic component in direct current operation or in alternating current operation, a white light having a luminance of 3000 cd/m² is intended to be formed as third electromagnetic radiation. The proportions of the red-green light and of the blue light for forming the white light are different—illustrated in FIG. 6B in the column having the reference sign 612. In order to form the white light having a luminance of 3000 cd/m², the second optically active structure 624 emits a light having a luminance of 2700 cd/m² and the first optically active structure 626, 628 emits a blue light having a luminance of 300 cd/m². With (II), for forming the white light, the lifetimes of the optically active structures 624, 626, 628 vary with respect to operation of the optically active structures 624, 626, 628 at 1000 cd/m²—illustrated for direct current operation in FIG. 6B in the column having the reference sign 614. As a result, the second optically active structure 624 can have a lifetime LT70 (2700 cd/m²) of 4508 hours and the first optically active structure 626 including a fluorescent emitter can have a lifetime LT70 (300 cd/m²) of 24 343 hours; and the first optically active structure 628 including a phosphorescent emitter can have a lifetime LT70 (300 cd/m²) of 6390 hours (see FIG. 1C). A first optically active structure including a fluorescent emitter that emits blue light currently has a significantly longer lifetime than a phosphorescent emitter that emits blue light. Independently of this, the lifetime of the first optically active structure significantly exceeds the lifetime of the second optically active structure. During this operation, the lifetime of the optoelectronic component is limited to the lifetime of the second optically active structure, i.e. to 4508 hours. This is owing to the fact that the blue light makes up a proportion of only approximately 10% of the white light. During long-term operation, a differential colour locus ageing becomes visible and exceeds the permissible deviation.

In the case of an optoelectronic component in which the optically active structures can be energized independently of one another (see description of FIGS. 5A-5B), the second optically active structure can be operated with a DC current and the first optically active structure can be operated in a pulsed manner.

The second optically active structure emits, as described above, the second electromagnetic radiation with a luminance of 2700 cd/m² and a lifetime of 4508 hours.

In order to form the white light with 3000 cd/m², the first optically active structure 626, 628 can be operated in a pulsed manner such that the first optically active structure 626, 628 has a lifetime LT70 (reference sign 622) corresponding approximately to the lifetime 614 of the second optically active structure 624. The optically active structures 624, 626/628 can be described by means of a stretched exponential decay. Given an approximately identical lifetime LT70, this results in no or a reduced different differential colour locus ageing.

For this purpose, the pulses of electromagnetic radiation of the first optically active structure 626 including a fluorescent emitter can have a maximum pulse height 620 having a value of 8700 cd/m² and a duty ratio 618 of 29.

In the case of a first optically active structure 628 including a phosphorescent emitter, the pulses of electromagnetic radiation can have a maximum pulse amplitude 620 having a value of 600 cd/m² and a duty ratio 618 of 2.

As a result, the lifetime of the first optically active structure 626, 628 can be reduced from the abovementioned values to 4520 hours and 4518 hours, respectively.

In the case of an optoelectronic component in which the optically active structures are energized in a manner dependent on one another (see description of FIGS. 5A-5B), the first optically active structure 626, 628 and the second optically active structure 624 can be energized in a pulsed manner for forming the white light with 3000 cd/m².

The pulses of the second electromagnetic radiation can have a maximum pulse height 632 having a value of 5400 cd/m² and a duty ratio 630 of 2. As a result, the second optically active structure can have a lifetime LT70 (5400 cd/m²) 634 of 3188 hours.

The pulses of the first electromagnetic radiation of the first optically active structure 626 including a fluorescent emitter can have a maximum pulse amplitude 632 having a value of 17 400 cd/m² and a duty ratio 630 of 58. As a result, the first optically active structure 626 including a fluorescent emitter can have a lifetime LT70 (17 400 cd/m²) 634 of 3196 hours.

In the case of a first optically active structure 628 including a phosphorescent emitter, the pulses of electromagnetic radiation can have a maximum pulse height 632 having a value of 1200 cd/m² and a duty ratio 630 of 4. As a result, the first optically active structure 628 including a phosphorescent emitter can have a lifetime LT70 (1200 cd/m²) 634 of 3195 hours.

The optoelectronic component can thus be driven in such a way that the differential colour locus ageing (see FIG. 1C, FIG. 1D) is reduced by means of the described reduction of the operating period of the optically active structures having a longer life in conjunction with identical third electromagnetic radiation averaged over time. On account of a permissible colour locus ageing being exceeded, the lifetime of optoelectronic components can be shorter than is given by the lifetimes of the optically active structures. By means of the described method for operating an optoelectronic component, the lifetime of the optoelectronic component can thus be increased by means of a reduction of the differential colour locus ageing.

Given known luminances and lifetimes of the two or more optically active regions, the optically active structure having the shortest lifetime can be operated with DC current for forming the third electromagnetic radiation. A greatly pulsed driving of the optically active structure having the shortest life would require a higher pulse height in the averaging over time for forming the third electromagnetic radiation. With (II) the lifetime of the optically active structure having the shortest life would thus be reduced further with respect to direct current operation. The optically active structure having a longer life is operated in a pulsed manner or in alternating current operation. The pulse parameters or AC current parameters can be chosen such that the optically active structures have similar lifetimes. The optically active structure having the shortest life can be operated in alternating current operation, but should be operated with a duty ratio close to direct current operation, for example MUX=2. If two or more optically active structures are operated in alternating current operation, it is possible, in a simplified manner, to use only one AC current source as an electrical energy supply.

In various embodiments, an optoelectronic component device and a method for operating an optoelectronic component are provided which make it possible to operate an OLED without a colour sensor with at least reduced colour locus deviation. As a result, a differential colour ageing can be avoided, such that the colour locus of light emitted by the optoelectronic component remains stable during long-term operation. Furthermore, a complex, electronically regulated colour control by means of a colour sensor and feedback to the driver of the optoelectronic component becomes optional or is no longer necessary. Furthermore, by means of the method, an optoelectronic component can be realised as a so-called “2 terminal device”, which has only two electrical terminals and is colour-locus-regulated, for example. Furthermore, an optoelectronic component can be realised which can be operated by means of an AC current driver that is more cost-effective with respect to a DC current driver. Furthermore, in the case of an OLED having a plurality of optically active structures, by connecting the antiparallel optically active structures in series, it is possible to realise luminaires suitable for an electricity grid, i.e. a transformation of the driver voltage is not necessary. Furthermore, established methods for producing the optoelectronic component can still be used, since, for example, the OLED in accordance with various configurations is formed very similarly to a white stacked OLED having a charge generating layer (CGL) structure. Furthermore, the optoelectronic component formed as an OLED having different OLED units can enable separate operation of phosphorescent emitter materials (red, green) and fluorescent emitter materials (blue).

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. An optoelectronic component device, comprising:
an optoelectronic component and a control device for driving the optoelectronic component;
wherein the optoelectronic component comprises a first optically active structure and a second optically active structure,
wherein the first optically active structure is designed for emitting a first electromagnetic radiation and ages in accordance with a first ageing function during operation; and
wherein the second optically active structure is designed for emitting a second electromagnetic radiation and ages in accordance with a second ageing function during operation;
wherein the optoelectronic component is formed in such a way that at least the first electromagnetic radiation is emitted in a first operating mode and at least the second electromagnetic radiation is emitted in a second operating mode;
wherein the control device is designed so as to reduce the difference between first ageing function and second ageing function during the operation of the optoelectronic component device.

2. The optoelectronic component device according to claim 1,
wherein the optoelectronic component is formed in such a way that the first ageing function and the second ageing function have an approximately identical ageing coefficient.

3. The optoelectronic component device according to claim 1,
wherein the first optically active structure is formed in such a way that the first electromagnetic radiation is a blue light.

4. The optoelectronic component device according to claim 1,
wherein the control device is formed in such a way as to drive the first optically active structure in the first operating mode with a first voltage profile and to drive the second optically active structure in the second operating mode with a second voltage profile, which is different from the first voltage profile.

5. A method for operating an optoelectronic component,
wherein the optoelectronic component comprises a first optically active structure and a second optically active structure,
wherein the first optically active structure is designed for emitting a first electromagnetic radiation and ages in accordance with a first ageing function during operation; and
wherein the second optically active structure is designed for emitting a second electromagnetic radiation and ages in accordance with a second ageing function during operation;
wherein the optoelectronic component is formed in such a way that at least the first electromagnetic radiation is emitted in a first operating mode and at least the second electromagnetic radiation is emitted in a second operating mode;
wherein the control device is designed so as to reduce the difference between first ageing function and second ageing function during the operation of the optoelectronic component device,
the method comprising:
driving the optoelectronic component in a predefined driving interval partly in the first operating mode and partly in the second operating mode in such a way as to reduce the difference between first ageing function and second ageing function during the operation of the optoelectronic component.

6. The method according to claim 5,
wherein the first optically active structure is formed in such a way that the first electromagnetic radiation is a blue light;
wherein the second optically active structure is formed in such a way that the second electromagnetic radiation is a yellow light or a green-red light; and/or
wherein the optoelectronic component is driven in such a way that the mixture of first electromagnetic radiation and second electromagnetic radiation in a driving interval is a white light.

7. The method according to claim 5,
wherein at least one property of a third electromagnetic radiation is formed by means of the amplitude, the frequency and/or the duty ratio of an AC current and/or an AC voltage.

8. The method according to claim 7,
wherein the AC current has a DC current proportion, or the AC voltage has a DC voltage proportion.

9. The method according to claim 8,
wherein the AC current and/or the AC voltage have/has a frequency of greater than approximately 30 Hz.

10. The method according to claim 5,
wherein the first operating mode comprises driving the first optically active structure with a first voltage profile and the second operating mode comprises driving the second optically active structure with a second voltage profile, which is different from the first voltage profile.

11. The method according to claim 10,
wherein the first voltage profile comprises at least one non-linear first range.

12. The method according to claim 5,
wherein the difference in the ageing function is less than a threshold value.

13. The method according to claim 12,
wherein the threshold value is a function with respect to the differential colour locus ageing of the first optically active structure and of the second optically active structure.

14. The method according to claim 12,
wherein the threshold value has an absolute value such that the colour locus shift linked by means of the differential colour locus ageing is less than 0.02 in Cx and/or Cy in a CIE standard chromaticity diagram.
